(19) United States
(12) Patent Application Publication
(10) Pub. No.: US 2015/0004383 A1
(43) Pub. Date: Jan. 1, 2015

(54) SUBSTRATE PROVIDED WITH A MULTILAYER HAVING THERMAL PROPERTIES, WHICH INCLUDES FOUR METALLIC FUNCTIONAL LAYERS

(71) Applicant: SAINT-GOBAIN GLASS FRANCE, Courbevoie (FR)

(72) Inventor: Etienne Sandre-Chardonnal, Paris (FR)

(73) Assignee: SAINT-GOBAIN GLASS FRANCE, Courbevoie (FR)

(21) Appl. No.: 14/372,563

(22) PCT Filed: Jan. 16, 2013
(86) PCT No.: PCT/FR13/50100

§ 371 Date: Jul. 16, 2014

(30) Foreign Application Priority Data
Jan. 16, 2012 (FR) 1250407

(51) Int. Cl. G02B 1/11; B60J 3/00; C03C 17/36; H01L 31/0216; H01L 51/44; H01L 51/52; E06B 3/67; H01L 31/0224

(52) U.S. Cl. CPC G02B 1/116; E06B 3/6715; B60J 3/007; H01L 31/022466; H01L 31/02168; H01L 51/442; H01L 51/5203; C03C 17/361; C03C 17/3626; C03C 17/3639; C03C 17/3657; C03C 17/3671; C03C 17/3678; C03C 17/3681; C03C 17/3655; C03C 2217/73
USPC 428/213

(57) ABSTRACT

A substrate, or a transparent glass substrate, including a thin-film multilayer including an alternation of four functional metallic layers, or functional layers based on silver or on a metal alloy containing silver, and five antireflection coatings, each antireflection coating including at least one antireflection layer, so that each functional metallic layer is positioned between two antireflection coatings. The thickness of the second, third, and fourth functional metallic layers starting from the substrate is substantially identical, with a ratio of the thickness of one layer to the thickness of the preceding layer between 0.9 and 1.1 inclusive of these values, and the thickness of the first functional metallic layer is about half the thickness of the second functional metallic layer, with a ratio of the thickness of the second metallic layer to the thickness of the first functional metallic layer between 1.9 and 2.2 inclusive of these values.

The invention relates to a transparent substrate, especially made of a rigid mineral material such as glass, said substrate being coated with a thin-film multilayer comprising several functional layers that can act on solar radiation and/or infrared radiation of long wavelength.

The invention relates more particularly to a substrate, especially a transparent glass substrate, provided with a thin-film multilayer comprising an alternation of “n” functional metallic layers, especially of functional layers based on silver or on a metal alloy containing silver, and of “(n+1)” antireflection coatings, with n being an integer=4, so that each functional layer is positioned between two antireflection coatings. Each coating comprises at least one antireflection layer, each coating being, preferably, composed of a plurality of layers, at least one layer of which, or even each layer of which, is an antireflection layer.

The invention relates more particularly to the use of such substrates for manufacturing thermal insulation and/or solar protection glazing. This glazing may equally be intended for equipping both buildings and vehicles, especially with a view to reducing air-conditioning load and/or preventing excessive overheating (called “solar control” glazing) and/or reducing the amount of energy dissipated to the outside (called “low-emissivity” glazing) brought about by the ever increasing use of glazed surfaces in buildings and vehicle passenger compartments.

These substrates may in particular be integrated into electronic devices and the multilayer may then act as an electrode for the conduction of a current (lighting device, display device, voltaic panel, electrochromic glazing, etc.) or may be integrated into glazing having particular functionalities, such as for example heated glazing, and in particular heated vehicle windshields.

Multilayers having four functional metallic layers are known.

In this type of multilayer, each functional layer is positioned between two antireflection coatings each comprising, in general, several antireflection layers which are each made of a material of nitride type and especially silicon nitride or aluminum nitride and/or of oxide type. From an optical point of view, the purpose of these coatings which flank the functional layer is to “antireflect” this functional layer.

A very thin blocker coating is however interposed sometimes between one or each antireflection coating and an adjacent functional layer: a blocker coating positioned beneath the functional layer in the direction of the substrate and a blocker coating positioned on the functional layer on the opposite side from the substrate and which protects this layer from any degradation during the deposition of the upper antireflection coating and during an optional high-temperature heat treatment of the bending and/or tempering type.

Multilayers having four functional layers are known from the prior art, for example from international Patent Application No. WO 2005/051858.

In the multilayers having four functional layers presented in that document, the thicknesses of all the functional layers are substantially identical, that is to say that the thickness of the first functional layer, closest to the substrate, is substantially identical to the thickness of the second functional layer which is substantially identical to the thickness of the third functional layer, or even which is substantially identical to the thickness of the fourth functional layer when there is a fourth functional layer. See, for example, example 24 from that document.

However, it appears that the configuration of the double glazing from example 24 of Application No. WO 2005/051858 is not entirely satisfactory since, even though its light transmission is quite high (58.0%), its light reflection quite low (12.2%) and its energy transmission quite low, its solar factor (which is by nature higher than the energy transmission) results in a selectivity that is not satisfactory; in addition, the color in transmission is not satisfactory either due to a value of a* in the Lab system that is very negative.

It appears that it would be preferable to obtain a light transmission in double glazing that is higher (of the order of 60%), a light reflection that is still as low (of the order of 12%) and a lower solar factor (of the order of 26%), in order to be able to obtain a high selectivity of the order of 2.3; it also appears that it would be preferable to obtain a color in reflection, both from the outside and from the inside, which is more neutral, in the blue-green range and which in addition varies little with the viewing angle.

One objective of the invention is thus to provide a multilayer that has these features.

Another objective is to provide a multilayer that has a very low sheet resistance in order, in particular, for the glazing integrating this multilayer to be able to exhibit a high energy reflection and/or a very low emissivity and/or to be able to be heated by applying a current between two busbars electrically connected to the multilayer, and also a high light transmission and a relatively neutral color, in particular in double glazing configuration or in laminated configuration, and for these properties to preferably be obtained after one (or more) high-temperature heat treatment(s) of the bending and/or tempering and/or annealing type, or even for these properties to be maintained within a restricted range whether or not the multilayer undergoes one (or more) of such heat treatment(s).

One subject of the invention is thus, in its broadest sense, a substrate, especially a transparent glass substrate, provided with a thin-film multilayer comprising an alternation of four functional metallic layers, especially of functional layers based on silver or a on metal alloy containing silver, and of five antireflection coatings, each antireflection coating comprising at least one antireflection layer, so that each functional metallic layer is positioned between two antireflection coatings, noteworthy in that the thickness of the second, third and fourth functional metallic layers starting from the substrate is substantially identical, with a ratio of the thickness of one layer to the thickness of the preceding layer that is between 0.9 and 1.1 inclusive of these values, and the thickness of the first functional metallic layer is around half the thickness of the second functional metallic layer, with a ratio of the thickness of the second metallic layer to the thickness of the first functional metallic layer that is between 1.9 and 2.2 inclusive of these values.

The antireflection coatings each located between two functional metallic layers have quite similar optical thicknesses. Each antireflection coating located between two functional metallic layers has, preferably, an optical thickness between 165 nm and 181 nm inclusive of these values in order to promote the obtaining of a color in reflection in the blue-green range. This is all the more surprising considering the imbalance between the thickness of the first functional metallic layer and the thickness of the other functional metallic layers.

The expression “color in the blue-green range” should be understood within the present invention to mean that, in the Lab color measurement system, a* is between 0 and −6.

Preferably, each antireflection coating located between two functional metallic layers consists solely of one or more antireflection layers. Preferably, there is therefore no absorbent layer in the dielectric coatings, so as not to decrease the light transmission.

The thickness of the first functional metallic layer is, preferably, around half the thickness of all the other functional metallic layers, with a ratio of the average of the thickness of the second, third and fourth functional metallic layers to the thickness of the first functional metallic layer that is between 1.9 and 2.5 inclusive of these values. This rule makes it possible to promote the obtaining of a color in external reflection that is in the blue-green range.

The term “row” is understood within the present invention to mean the numbering, in integers, of each functional layer starting from the substrate: the functional layer closest to the substrate being the functional layer of row 1 or first functional layer, the next moving away from the substrate being that of row 2 or second functional layer, etc.

The expression “ratio of the thickness of one layer to the thickness of the preceding layer” should thus be understood to mean the ratio of the thickness of the layer in question to the thickness of the layer of the row immediately below.

The thickness of each functional layer is, preferably, between 6 and 20 nm inclusive of these values, in order to obtain a high enough light transmission.

The thickness e₄₀ in nm of the first functional metallic layer starting from the substrate (that of row 1) is, preferably, such that: 5.5≦e₄₀≦11 in nm, and preferably 6≦e₄₀≦10.

The thickness e₈₀ in nm of the second functional metallic layer starting from the substrate (that of row 2) is, preferably, such that: 11≦e₈₀≦22 in nm, and preferably 12≦e₈₀≦20.

The thickness e₁₂₀ in nm of the third functional metallic layer starting from the substrate (that of row 3) is, preferably, such that: 11≦e₁₂₀≦22 in nm, and preferably 12≦e₁₂₀≦20.

The thickness e₁₆₀ in nm of the fourth functional metallic layer starting from the substrate (that of row 4) is, preferably, such that: 11≦e₁₆₀≦22 in nm, and preferably 12≦e₁₆₀≦20.

These thickness ranges for the functional metallic layers are the ranges for which the best results are obtained: high light transmission in double glazing, low light reflection and lower solar factor, in order to be able to obtain a high selectivity with a color in reflection, both from the outside and from the inside, which is neutral, in the blue-green range.

In one preferred variant, the total thickness of the four functional metallic layers is between 30 and 70 nm inclusive of these values, or even this total thickness is between 35 and 65 nm.

It is important to note here that the particular spread in the distribution of the thicknesses of the four functional layers is not the same as the spread in the distribution of the thicknesses of all the layers of the multilayer (taking into account the antireflection layers).

Unless otherwise mentioned, the thicknesses cited in the present document are physical or actual thicknesses (and not optical thicknesses).

The expression “optical thickness” is understood within the invention to mean, as is customary, the product of the physical (or actual) thickness of the layer multiplied by its refractive index measured as usual at 550 nm.

The expression “total optical thickness” is understood within the invention to mean the sum of all the optical thicknesses of the layers in question, each optical thickness being, as explained above, the product of the physical (or actual) thickness of the layer multiplied by its refractive index measured as usual at 550 nm.

Thus, the total optical thickness of the first antireflection coating (that of row 1) subjacent to the first functional metallic layer is formed from the sum of all the optical thicknesses of the dielectric layers of this coating which are positioned between the substrate and the first functional metallic layer or between the substrate and the underblocker coating of the first metallic layer if this underblocker coating is present.

Similarly, the total optical thickness of the last antireflection coating (that of row 5), superjacent to the fourth functional metallic layer is formed from the sum of all the optical thicknesses of the dielectric layers of this coating which are positioned on top of the fourth functional metallic layer, on the opposite side to the substrate, or on top of the overblocker coating of this fourth functional metallic layer if this overblocker coating is present.

The total optical thickness of an intermediate antireflection coating (those of rows 2, 3 and 4), superjacent to a functional metallic layer and subjacent to the following functional metallic layer on moving away from the substrate, is formed from the sum of all the optical thicknesses of the dielectric layers of this coating which are positioned between these two functional metallic layers, on top of the overblocker coating of the functional metallic layer if it is present and underneath the underblocker coating of the following functional metallic layer if it is present.

Furthermore, when mention is made of a vertical positioning of a layer (e.g.: underneath/on top of), it is always by considering that the carrier substrate is positioned horizontally, on the bottom, with the multilayer on it. When it is specified that a layer is deposited directly onto another, this means that there cannot be one (or more) layer(s) inserted between these two layers. The row of the functional layers is in this case always defined starting from the substrate bearing the multilayer (substrate on the face of which the multilayer is deposited) and referring to layers of the same nature.

In one particular variant of the invention, each of the antireflection coatings comprises at least one antireflection layer based on silicon nitride, optionally doped with the aid of at least one other element, such as aluminum. This is particularly advantageous for thin-film multilayers to be bent/tempered or for bendable/temperable thin-film multilayers.

In another particular variant of the invention, the last layer of each antireflection coating subjacent to a functional layer is an antireflection wetting layer based on crystalline oxide, especially based on zinc oxide, optionally doped with the aid of at least one other element, such as aluminum, in order to promote the obtaining of crystalline functional layers.

The present invention furthermore relates to glazing incorporating at least one substrate according to the invention, optionally combined with at least one other substrate and especially multiple glazing of the double glazing or triple glazing or laminated glazing type and in particular laminated glazing comprising means for the electrical connection of the thin-film multilayer in order to make it possible to produce heated laminated glazing, it being possible for said substrate bearing the multilayer to be bent and/or tempered.

Each substrate of the glazing may be clear or tinted. At least one of the substrates may especially be made of bulk-tinted glass. The choice of coloration type will depend on the level of light transmission and/or on the colorimetric appearance that is/are desired for the glazing once its manufacture has been completed.

The glazing according to the invention may have a laminated structure, especially combining at least two rigid substrates of the glass type with at least one sheet of thermoplastic polymer, so as to have a structure of the following type: glass/thin-film multilayer/sheet(s)/glass. The polymer may especially be based on polyvinyl butyral (PVB), ethylene/vinyl acetate (EVA), polyethylene terephthalate (PET) or polyvinyl chloride (PVC).

The glazing may then have a structure of the type: glass/thin-film multilayer/polymer sheet(s)/glass.

The glazing according to the invention is capable of undergoing a heat treatment without the thin-film multilayer being damaged. It is therefore optionally bent and/or tempered.

The glazing may be bent and/or tempered when formed from a single substrate, that provided with the multilayer. This is then referred to as “monolithic” glazing. If the glazing is bent, especially for the purpose of forming glazing for vehicles, the thin-film multilayer is preferably on a face which is at least partly nonplanar.

The glazing may also be multiple glazing, especially double glazing, it being possible for at least the substrate bearing the multilayer to be bent and/or tempered. It is preferable in a multiple glazing configuration for the multilayer to be placed so as to face the intermediate gas-filled space. In a laminated structure, the substrate bearing the multilayer may be in contact with the polymer sheet.

The glazing may also be a triple glazing consisting of three sheets of glass separated, in pairs, by a gas-filled space. In a triple-glazing structure, the substrate bearing the multilayer may be on face 2 and/or on face 5, when considering that the incident direction of the sunlight passes through the faces in the order of increasing face number.

When the glazing is monolithic glazing or multiple glazing of the double glazing, triple glazing or laminated glazing type, at least the substrate bearing the multilayer may be made of bent or tempered glass, it being possible for this substrate to be bent or tempered before or after deposition of the multilayer.

The invention also relates to the use of the substrate according to the invention for producing glazing having high energy reflection and/or glazing having very low emissivity and/or heated glazing with a transparent coating heated by the Joule effect.

The invention also relates to the use of the substrate according to the invention for producing a transparent electrode of electrochromic glazing or of a lighting device or of a display device or of a photovoltaic panel.

The substrate according to the invention may, in particular, be used for producing a substrate having high energy reflection and/or a substrate having very low emissivity and/or a heated transparent coating of heated glazing.

The substrate according to the invention may, in particular, be used for producing a transparent electrode of electrochromic glazing (this glazing being monolithic glazing or multiple glazing of the double glazing or triple glazing or laminated glazing type) or of a lighting device or of a display screen or of a photovoltaic panel. (The term “transparent” should be understood here as meaning “non-opaque”).

The multilayer according to the invention makes it possible to obtain a substrate coated with a multilayer and which has a high light transmission (>55%, and even >60%), a low light reflection (<14%), a high solar factor and a color in reflection that is not very pronounced (with values of a* and b* in the Lab system that are close to zero) and that also varies little as a function of the viewing angle.

The multilayer according to the invention thus makes it possible to achieve a high selectivity, of greater than 2.1.

The details and advantageous features of the invention will emerge from the following nonlimiting examples, illustrated by means of the appended figures:

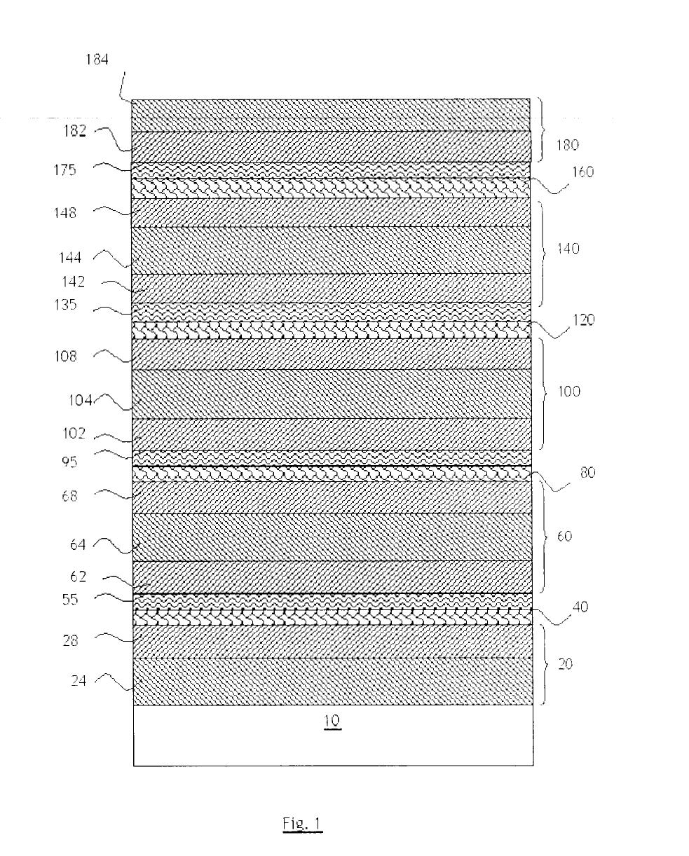

FIG. 1 illustrates an example of the structure of a multilayer with four functional metallic layers according to the invention;

FIG. 2 illustrates the variations of color in reflection as a function of the angle in the Lab system for example 1, observed from the outside (“out”) and from the inside (“in”);

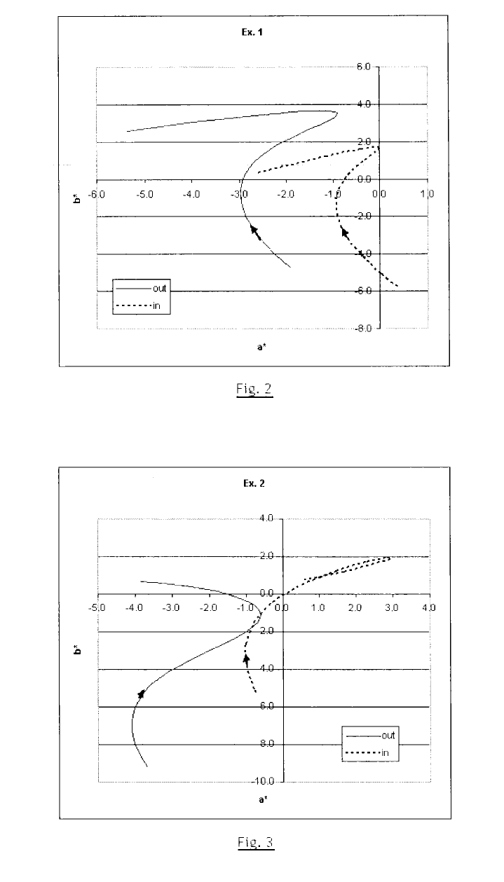

FIG. 3 illustrates the variations of color in reflection as a function of the angle in the Lab system for example 2, observed from the outside (“out”) and from the inside (“in”);

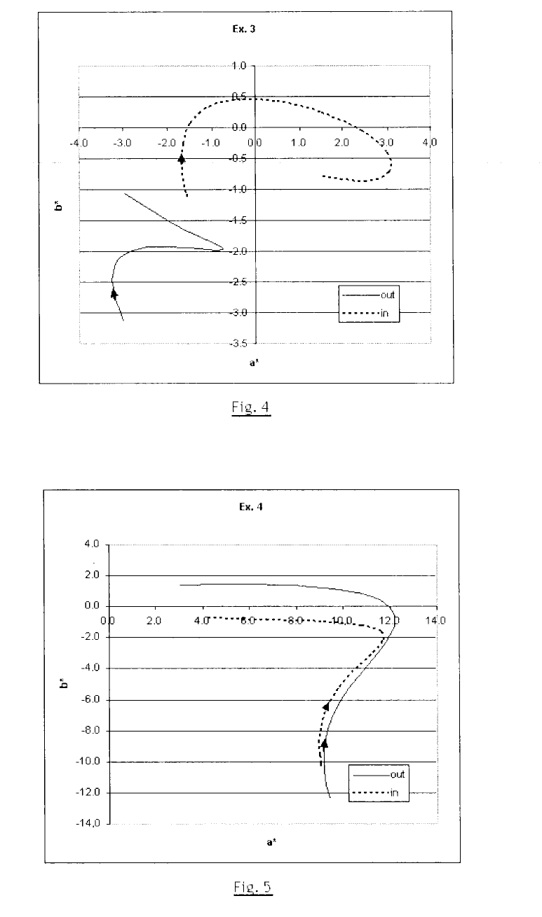

FIG. 4 illustrates the variations of color in reflection as a function of the angle in the Lab system for example 3, observed from the outside (“out”) and from the inside (“in”);

FIG. 5 illustrates the variations of color in reflection as a function of the angle in the Lab system for example 4, observed from the outside (“out”) and from the inside (“in”); and

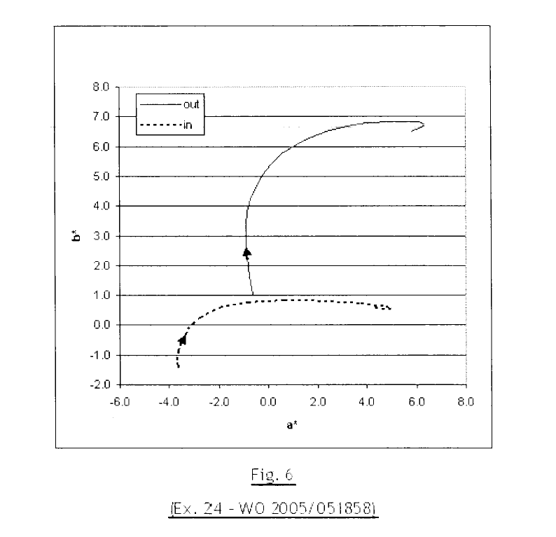

FIG. 6 illustrates the variations of color in reflection as a function of the angle in the Lab system for example 24 from international Patent Application No. WO 2005/051858, observed from the outside (“out”) and from the inside (“in”).

In FIG. 1, the proportions between the various elements have not been respected in order to make them easier to examine. For FIGS. 2 to 6, the arrows indicate the variations obtained from 0° with respect to the normal to the outside surface (start of the curve) up to an angle of 70° with respect to the normal to the outside surface (end of the curve following the direction of the arrow).

FIG. 1 illustrates a multilayer structure having four functional metallic layers 40, 80, 120, 160, this structure being deposited on a transparent glass substrate 10.

Each functional layer 40, 80, 120, 160 is positioned between two antireflection coatings 20, 60, 100, 140, 180 so that the first functional layer 40 starting from the substrate is positioned between the antireflection coatings 20, 60, the second functional layer 80 is positioned between the antireflection coatings 60, 100, the third functional layer 120 is positioned between the antireflection coatings 100, 140 and the fourth functional layer 160 is positioned between the antireflection coatings 140 and 180.

These antireflection coatings 20, 60, 100, 140, 180 each comprise at least one antireflection dielectric layer 24, 28; 62, 64, 68; 102, 104, 108; 142, 144, 148; 182, 184.

Optionally, on the one hand each functional layer 40, 80, 120, 160 may be deposited on an underblocker coating (not illustrated) positioned between the antireflection coating subjacent to the functional layer and the functional layer and, on the other hand, each functional layer 40, 80, 120, 160 may be deposited directly beneath an overblocker coating 55, 95, 135, 175 positioned between the functional layer and the antireflection coating superjacent to this layer.

These blocker coatings are not taken into consideration in the optical definition of the antireflection coatings of the multilayer.

A first series of four examples was carried out. These examples are numbered from 1 to 4 hereinbelow.

For these examples, the antireflection coatings 20, 60, 100, 140, 180 are only defined by their optical thicknesses (by considering that the refractive index of the antireflection material that makes up the antireflection coatings is measured at 550 nm, as is customary).

Table 1 below summarizes the thicknesses, in nanometers, of each layer or coating that forms the multilayer as a function of their positions with respect to the substrate bearing the multilayer (last line at the bottom of the table); the subscripts of the thicknesses from the 1st column correspond to the references from FIG. 1.

TABLE 1

| | | Ex. 1 | Ex. 2 | Ex. 3 | Ex. 4 |
|---|---|---|---|---|---|
| e₁₈₀ | Dielectric 5 | 91 | 86 | 75 | 85 |
| e₁₆₀ | Ag4 | 17.1 | 17.1 | 17.2 | 15.5 |
| e₁₄₀ | Dielectric 4 | 181 | 178 | 176 | 175 |
| e₁₂₀ | Ag3 | 15.7 | 15.8 | 13.3 | 17.1 |
| e₁₀₀ | Dielectric 3 | 168 | 167 | 141 | 172 |
| e₈₀ | Ag2 | 15.2 | 14.3 | 8.6 | 15.1 |
| e₆₀ | Dielectric 2 | 175 | 165 | 118 | 165 |
| e₄₀ | Ag1 | 7.7 | 6.7 | 6.2 | 9.5 |
| e₂₀ | Dielectric 1 | 89 | 45 | 67 | 80 |
| | Glass | | | | |

Table 2 below summarizes the ratios of the thicknesses of the functional layers:

TABLE 2

| | Ex. 1 | Ex. 2 | Ex. 3 | Ex. 4 |
|---|---|---|---|---|
| e₁₆₀/e₁₂₀ | 1.09 | 1.08 | 1.30 | 0.91 |
| e₁₂₀/e₈₀ | 1.03 | 1.10 | 1.55 | 1.13 |
| e₈₀/e₄₀ | 1.98 | 2.13 | 1.39 | 1.60 |
| ((e₈₀ + e₁₂₀ + e₁₆₀)/3)/e₄₀ | 2.08 | 2.35 | 2.10 | 1.67 |

Table 3 summarizes for these examples 1 to 4 the main optical features measured for the substrate bearing the multilayer integrated into double glazing having the structure: 6 mm glass/15 mm intermediate argon-filled space/6 mm glass, the multilayer being positioned on face 2 (face 1 of the glazing being the outermost face of the glazing, as is customary).

TABLE 3

| | | Ex. 1 | Ex. 2 | Ex. 3 | Ex. 4 |
|---|---|---|---|---|---|
| T_{L} | % | 60.0 | 59.8 | 59.9 | 61.7 |
| a*_{T} | | −8.4 | −8.0 | −7.2 | −11.4 |
| b*_{T} | | 3.3 | 4.0 | 3.1 | 4.2 |
| R_{Lext} | % | 12.5 | 12.6 | 12.1 | 9.1 |
| a*_{Rext} | | −1.9 | −3.7 | −3.0 | 9.4 |
| b*_{Rext} | | −4.8 | −9.2 | −3.1 | −12.4 |
| a*_{Rext-45°} | | −1.0 | −1.0 | −1.3 | 12.1 |
| b*_{Rext-45°} | | 3.2 | −2.1 | −1.9 | −1.5 |
| a*_{Rext-60°} | | −2.5 | −1.5 | −1.1 | 9.2 |
| b*_{Rext-60°} | | 3.5 | 0.0 | −1.8 | 1.2 |
| R_{Lint} | % | 14.0 | 14.1 | 16.1 | 11.0 |
| a*_{Rint} | | 0.4 | −0.7 | −1.5 | 9.1 |
| b*_{Rint} | | −5.7 | −5.3 | −1.1 | −10.3 |
| SF | % | 26.4 | 26.4 | 28.3 | 26.6 |

For this double glazing,
T_{L} indicates the light transmission in the visible range in %, measured under illuminant A/10° observer conditions;
a*_{T} and b*_{T} indicate the colors in transmission a* and b* in the Lab system measured under illuminant D65/10° observer conditions and thus measured substantially perpendicular to the glazing;
R_{Lext} indicates the light reflection in the visible range in %, measured under illuminant A/10° observer conditions from the side of the outermost face, face 1;
a*_{Rext} and b*_{Rext} indicate the colors in reflection a* and b* in the Lab system measured under illuminant D65/10° observer conditions from the side of the outermost face and thus measured substantially perpendicular to the glazing;
a*_{Rext-45°} and b*_{Rext-45°} indicate the colors in reflection a* and b* in the Lab system measured under illuminant D65/10° observer conditions from the side of the outermost face and measured substantially with an angle of 45° with respect to the perpendicular to the glazing;
a*_{Rext-60°} and b*_{Rext-60°} indicate the colors in reflection a* and b* in the Lab system measured under illuminant D65/10° observer conditions from the side of the outermost face and measured substantially with an angle of 60° with respect to the perpendicular to the glazing;
R_{Lint} indicates the light reflection in the visible range in %, measured under illuminant A/10° observer conditions from the side of the innermost face, face 4;
a*_{Rint} and b*_{Rint} indicate the colors in reflection a* and b* in the Lab system measured under illuminant D65/10° observer conditions from the side of the innermost face and thus measured substantially perpendicular to the glazing;
SF indicates the solar factor, that is to say the percentage of the total energy entering the room through the glazing over the total incident solar energy, calculated according to standard EN 410.

For examples 1 and 2 according to the invention, the three functional layers furthest from the substrate thus have almost identical thicknesses: on the one hand, the ratio of the thickness e₁₆₀ of the fourth functional layer to the thickness e₁₂₀ of the third functional layer and, on the other hand, the ratio of the thickness e₁₂₀ of the third functional layer to the thickness e₈₀ of the second functional layer are almost identical; these ratios are between 0.9 and 1.2 and more precisely still between 1.0 and 1.15.

For these examples 1 and 2 according to the invention, the functional layer closest to the substrate has a thickness e₄₀ of around half, or even less than half, the thickness e₈₀ of the second functional layer (cf. second-to-last line of table 2); the ratios of the thickness e₈₀ of the second functional layer to the thickness e₄₀ of the first functional layer are between 1.9 and 2.2.

For these examples 1 and 2 according to the invention, the functional layer closest to the substrate has a thickness e₄₀ of around half, or even less than half, the average thickness of all the other functional layers (cf. last line of table 2); theses ratios are between 1.9 and 2.5 and more precisely still between 2.0 and 2.4.

For example 3, which is not according to the invention, the thicknesses of the functional layers gradually increase on moving away from the substrate, with a ratio of the order of 1.3 to 1.5 of the thickness of one functional layer to the thickness of the preceding functional layer in the direction of the substrate.

For example 3, which is not according to the invention, even though the functional layer closest to the substrate has a thickness e₄₀ of around half the average thickness of all the other functional layers (cf. last line of table 2), the functional layer closest to the substrate does not have a thickness e₄₀ of around half the thickness e₈₀ of the second functional layer (cf. second-to-last line of table 2).

For example 4, which is not according to the invention, the three functional layers furthest from the substrate have almost identical thicknesses: on the one hand, the ratio of the thickness e₁₆₀ of the fourth functional layer to the thickness e₁₂₀ of the third functional layer and, on the other hand, the ratio of the thickness e₁₂₀ of the third functional layer to the thickness e₈₀ of the second functional layer are almost identical; these ratios are between 0.9 and 1.2.

For example 4, which is not according to the invention, the functional layer closest to the substrate has a thickness e₄₀ that is certainly smaller than the thickness of the second functional layer (cf. second-to-last line of table 2), but the ratio of the thickness e₈₀ of the second functional layer to the thickness e₄₀ of the first functional layer is less than 1.9.

For example 4, which is not according to the invention, the functional layer closest to the substrate has a thickness that is much larger than half the average thickness of all the other functional layers (cf. last line of table 2).

Studying table 3 shows that it is possible to produce a multilayer with four functional metallic layers that has a light reflection that is low and flat throughout the visible range, with very steep slopes in the UV and infrared ranges, and the transmission spectrum of which thus clearly approaches the ideal square-wave bandpass spectrum, thus making it possible to obtain a very advantageous selectivity (T_{L}/SF ratio), of the order of 60/26; this is what was obtained with examples 1 and 2.

Moreover, the color in reflection, both on the external side and on the internal side, is contained within the blue-green range and varies little with the angle, as can be seen in FIGS. 2 and 3 respectively for examples 1 and 2.

In FIG. 2, it is possible to find, for example 1, the values from table 3 for the color in external reflection (“out”, as solid line) and in particular at 0°, i.e. to the normal, of a*_{Rext}=−1.9 and b*_{Rext}=−4.8; this is the start of the solid line curve.

In FIG. 2, it is possible to find, for example 1, the values from table 3 for the color in internal reflection (“in”, as dotted line) and in particular at 0°, i.e. to the normal, of a*_{Rext}=0.4 and b*_{Rext}=−5.7; this is the start of the dotted line curve.

Example 3 has a worse selectivity than that of examples 1 and 2, of around 60/28. Moreover, the color in reflection, both on the external side and on the internal side, varies a lot with the angle, as can be seen in FIG. 4.

Example 4 has a slightly better selectivity than that of examples 1 and 2, of around 61/26, but has a reddish color in reflection which varies a lot with the angle, as can be seen in FIG. 5.

Example 24 from Application No. WO 2005/051858 was itself also the subject of a simulation analysis, with the same computerized tool as examples 1 to 4 above. The result is illustrated in FIG. 6.

Both the color in external reflection and the color in internal reflection vary a lot with the angle.

For example 5 below, based on example 2 above, the thin-film multilayer is deposited on a substrate made of clear soda-lime glass having a thickness of 6 mm, sold by SAINT-GOBAIN.

For this example, the conditions for depositing the layers, which were deposited by sputtering (magnetron sputtering), are the following:

TABLE 4

| | | Deposition | | Index at |
|---|---|---|---|---|
| Layer | Target employed | pressure | Gas | 550 nm |
| SiAlN | Si:Al at 92:8 wt % | 3.2 × 10⁻³ mbar | Ar/(Ar + N₂) | 2.03 |
| | | | at 55% | |
| ZnO | Zn:Al at 98:2 wt % | 1.8 × 10⁻³ mbar | Ar/(Ar + O₂) | 1.95 |
| | | | at 63% | |
| Ti | Ti | 2.5 × 10⁻³ mbar | Ar at 100% | |
| Ag | Ag | 3 × 10⁻³ mbar | Ar at 100% | |

Table 5 below summarizes the materials and the thicknesses, in nanometers, of each layer and the composition of the layers that form the multilayer of example 5 as a function of their positions with respect to the substrate bearing the multilayer (last line at the bottom of the table); the numbers in the 1st and 2nd columns, and also the subscripts in the last column, correspond to the references from FIG. 1.

TABLE 5

| | | | | Optical |
|---|---|---|---|---|
| | | | Ex. 5 | thicknesses (nm) |
| 180 | 184 | SiAlN | 36.3 | e₁₈₀ = 81.49 |
| | 182 | ZnO | 4 | |
| 175 | | Ti | 0.5 | |
| 160 | | Ag4 | 17.1 | |
| 140 | 148 | ZnO | 4 | e₁₄₀ = 168.86 |
| | 144 | SiAlN | 75.5 | |
| | 142 | ZnO | 4 | |
| 135 | | Ti | 0.5 | |
| 120 | | Ag3 | 15.8 | |
| 100 | 108 | ZnO | 4 | e₁₀₀ = 158.71 |
| | 104 | SiAlN | 70.5 | |
| | 102 | ZnO | 4 | |
| 95 | | Ti | 0.5 | |
| 80 | | Ag2 | 14.4 | |
| 60 | 68 | ZnO | 4 | e₆₀ = 156.89 |
| | 64 | SiAlN | 69.6 | |
| | 62 | ZnO | 4 | |
| 55 | | Ti | 0.5 | |
| 40 | | Ag1 | 6.6 | |
| 20 | 28 | Zn0 | 4 | e₂₀ = 41.70 |
| | 24 | SiAlN | 16.7 | |
| 10 | | Glass | | |

Each antireflection coating 20, 60, 100, 140 subjacent to a functional layer 40, 80, 120, 160 comprises a last wetting layer 28, 68, 108, 148 based on aluminum-doped crystalline zinc oxide and which is in contact with the functional layer 40, 80, 120, 160 deposited just above.

Each antireflection coating 20, 60, 100, 140, 180 comprises a layer 24, 64, 104, 144, 184 with an average index, based on aluminum-doped silicon nitride referred to here as SiAlN for the sake of simplification even though the actual nature of the layer is in fact Si₃N₄:Al as explained above.

These silicon nitride-based layers are important for obtaining the oxygen barrier effect during the heat treatment.

Example 5 thus has the additional advantage of being temperable and bendable.

It was verified that this example 5 actually has the features indicated for example 2 in table 3 above, to within measurement errors and uncertainties, and those indicated in FIG. 3.

Due to the large total thickness of the silver layers (and therefore the low sheet resistance obtained) and also the good optical properties (in particular the light transmission in the visible range), it is possible, moreover, to use the substrate coated with the multilayer according to the invention to produce a transparent electrode substrate.

This transparent electrode substrate may be suitable for an organic light-emitting device, in particular by replacing a portion of the silicon nitride layer 184 from example 5 with a conductive layer (having, in particular, a resistivity of less than 10⁵Ω·cm) and especially an oxide-based layer. This layer may be, for example, made of tin oxide or based on zinc oxide optionally doped with Al or Ga, or based on a mixed oxide and especially on indium tin oxide ITO, indium zinc oxide IZO, tin zinc oxide SnZnO that is optionally doped (for example with Sb, F). This organic light-emitting device may be used for producing a lighting device or a display device (screen).

Generally, the transparent electrode substrate may be suitable as a heated substrate for heated glazing and in particular a heated laminated windshield. It may also be suitable as a transparent electrode substrate for any electrochromic glazing, any display screen, or else for a photovoltaic cell and especially for a front face or a rear face of a transparent photovoltaic cell.

The present invention is described in the aforegoing by way of example. It is understood that a person skilled in the art is capable of carrying out various variants of the invention without however departing from the scope of the patent as defined by the claims.

1-12. (canceled)

13. A substrate or a transparent glass substrate, comprising:
a thin-film multilayer comprising an alternation of four functional metallic layers, or of functional layers based on silver or on a metal alloy containing silver, and five antireflection coatings, each antireflection coating comprising at least one antireflection layer, so that each functional metallic layer is positioned between two antireflection coatings,
wherein thicknesses of the second, third, and fourth functional metallic layers starting from the substrate is substantially identical, with a ratio of the thickness of one layer to the thickness of the preceding layer that is between 0.9 and 1.1 inclusive of these values, and
the thickness of the first functional metallic layer is about half the thickness of the second functional metallic layer, with a ratio of the thickness of the second metallic layer to the thickness of the first functional metallic layer that is between 1.9 and 2.2 inclusive of these values.

14. The substrate as claimed in claim 13, wherein each antireflection coating located between two functional metallic layers has an optical thickness between 165 nm and 181 nm inclusive of these values.

15. The substrate as claimed in claim 13, wherein the thickness of the first functional metallic layer is about half the thickness of all the other functional metallic layers, with a ratio of the average of the thickness of the second, third, and fourth functional metallic layers to the thickness of the first functional metallic layer that is between 1.9 and 2.5 inclusive of these values.

16. The substrate as claimed in claim 13, wherein the thickness e₄₀ in nm of the first functional metallic layer starting from the substrate is such that: 5.5≦e₄₀≦11 in nm, or 6≦e₄₀≦10.

17. The substrate as claimed in claim 13, wherein the thickness e₈₀ in nm of the second functional metallic layer starting from the substrate is such that: 11≦e₈₀≦22 in nm, or 12≦e₈₀≦20.

18. The substrate as claimed in claim 13, wherein the thickness e₁₂₀ in nm of the third functional metallic layer starting from the substrate is such that: 11≦e₁₂₀≦22 in nm, or 12≦e₁₂₀≦20.

19. The substrate as claimed in claim 13, wherein the thickness e₁₆₀ in nm of the fourth functional metallic layer starting from the substrate is such that: 11≦e₁₆₀≦22 in nm, or 12≦e₁₆₀≦20.

20. The substrate as claimed in claim 13, wherein the total thickness of the four functional metallic layers is between 30 and 70 nm inclusive of these values, or the total thickness is between 35 and 65 nm.

21. The substrate as claimed in claim 13, wherein each of the antireflection coatings comprises at least one antireflection layer based on silicon nitride, or doped with aid of at least one other element or aluminum.

22. The substrate as claimed in claim 13, wherein the last layer of each antireflection coating subjacent to a functional layer is an antireflection wetting layer based on crystalline oxide, or based on zinc oxide, or doped with aid of at least one other element or aluminum.

23. A glazing incorporating at least one substrate as claimed in claim 13, combined with at least one other substrate or multiple glazing of the double glazing or triple glazing or laminated glazing type or laminated glazing comprising means for electrical connection of the thin-film multilayer to make it possible to produce heated laminated glazing, or the substrate bearing the multilayer being bent and/or tempered.

24. The use of the substrate as claimed in claim 13, for producing a heated transparent coating of heated glazing or for producing a transparent electrode of electrochromic glazing or of a lighting device or of a display device or of a photovoltaic panel.
